(19) United States
(12) Patent Application Publication
(10) Pub. No.: US 2019/0281733 A1
(43) Pub. Date: Sep. 12, 2019

(54) ROTATING ELECTRIC MACHINE

(71) Applicant: DENSO CORPORATION, Kariya-city (JP)

(72) Inventors: Masashi MATSUHARA, Kariya-city (JP); Nobuo ISOGAI, Kariya-city (JP)

(73) Assignee: DENSO CORPORATION, Kariya-city (JP)

(21) Appl. No.: 16/292,778

(22) Filed: Mar. 5, 2019

(30) Foreign Application Priority Data
Mar. 9, 2018 (JP) 2018-042857

(51) Int. Cl. H05K 7/20; H02K 11/33; H02K 9/06; H02K 5/14; H02K 1/16; H02K 1/28; H02K 7/00

(52) U.S. Cl. CPC H05K 7/20909; H02K 11/33; H02K 9/06; H02K 7/006; H02K 1/16; H02K 1/28; H02K 5/141

(57) ABSTRACT

A rotating electric machine includes a rotating shaft with a rotation axis, a rotor, a stator, a housing, a plurality of control modules and a cover. The housing rotatably supports the rotating shaft and accommodates the rotor and the stator. The housing has a shaft-supporting part that supports an end portion of the rotating shaft. The control modules are arranged outside the shaft-supporting part of the housing and around the rotating shaft. The control modules each include a plurality of switching elements and a heat sink provided only on the rotation axis side of the switching elements. The cover, which covers the control modules, has a bottom part arranged on an opposite side of the control modules to the shaft-supporting part of the housing. End surfaces of the heat sinks of the control modules are formed to extend along an inner wall surface of the bottom part of the cover.

### CROSS-REFERENCE TO RELATED APPLICATION

This application is based on and claims priority from Japanese Patent Application No. 2018-42857 filed on Mar. 9, 2018, the contents of which are hereby incorporated by reference in their entirety into this application.

### BACKGROUND

### 1 Technical Field

The present disclosure relates to rotating electric machines.

### 2 Description of Related Art

There are known rotating electric machines that generate torque upon being supplied with electric power and generate electric power upon being supplied with torque. For example, Japanese Patent Publication No. JP4500300B2 discloses a rotating electric machine that includes a machine main body, which includes a stator and a rotor, and a control section for controlling electric power supplied from an external battery to the machine main body.

In the rotating electric machine disclosed in the above patent document, the control section includes three control modules each having a pair of switching elements sealed with resin. The control modules are arranged around the rotation axis of a rotating shaft of the machine main body. Moreover, in each of the control modules, there are provided two heat sinks, respectively on the rotation axis side of the switching elements and the opposite side of the switching elements to the rotation axis (or on the radially inner and radially outer sides of the switching elements), for cooling the switching elements.

Moreover, in the rotating electric machine disclosed in the above patent document, cooling air is caused by rotation of cooling fans included in the machine main body to flow from the outside to the inside of the rotating electric machine and make contact with the heat sinks of the control modules, thereby cooling the switching elements of the control modules.

However, in the rotating electric machine disclosed in the above patent document, to have all of the heat sinks of the control modules exposed to the cooling air, it is necessary to form, in a frame that receives both the stator and the rotor, ventilation holes on both the rotation axis side of the switching elements and the opposite side of the switching elements to the rotation axis. Consequently, the mechanical strength of the frame may be excessively lowered due to the ventilation holes formed therein. Moreover, the cooling air flowing through the heat sinks on the opposite side of the switching elements to the rotation axis may collide with the cooling air having flowed through the heat sinks on the rotation axis side of the switching elements, thereby making it impossible to realize a smooth flow of the cooling air in the rotating electric machine. Consequently, it may become difficult to sufficiently cool the switching elements of the control modules.

### SUMMARY

According to the present disclosure, there is provided a rotating electric machine which includes a rotating shaft, a rotor, a stator, a housing, a plurality of control modules and a cover. The rotating shaft has a rotation axis about which the rotating shaft is rotatable. The rotor is fixed on the rotating shaft to rotate together with the rotating shaft. The stator is provided radially outside the rotor and includes a stator coil. The housing rotatably supports the rotating shaft and accommodates both the rotor and the stator therein. The housing has a shaft-supporting part that supports an end portion of the rotating shaft. The control modules are capable of supplying multi-phase alternating current to the stator coil and rectifying multi-phase alternating current generated in the stator coil into direct current. The control modules are arranged outside the shaft-supporting part of the housing and around the rotating shaft. Each of the control modules includes a plurality of switching elements electrically connected with the stator coil, and a heat sink provided only on a rotation axis side, where the rotation axis of the rotating shaft is located, of the switching elements. The cover covers the control modules on an outside of the housing. The cover has a bottom part arranged on an opposite side of the control modules to the shaft-supporting part of the housing. Moreover, each of the heat sinks of the control modules has an end surface facing an inner wall surface of the bottom part of the cover; the end surface is formed to extend along the inner wall surface of the bottom part of the cover.

With the above configuration, the heat sinks of the control modules are provided only on the rotation axis side (i.e., only on the radially inner side) of the switching elements. Therefore, the flow of the cooling air passing through the heat sinks is relatively simple. Consequently, the efficiency of cooling the switching elements is prevented from being lowered due to stagnation of the cooling air caused by collision between different flows of the cooling air. Moreover, providing the heat sinks on the rotation axis side of the switching elements, the contact area of the heat sinks with the cooling air can be maximized.

Furthermore, with the above configuration, the end surfaces of the heat sinks, which face the inner wall surface of the bottom part of the cover, are formed to extend along the inner wall surface of the bottom part of the cover. Consequently, the length of the heat sinks in a direction parallel to the rotation axis of the rotating shaft and thus the contact area of the heat sinks with the cooling air can be maximized.

Accordingly, with the above configuration, it is possible to maximize the contact area of the heat sinks with the cooling air, thereby improving the efficiency of cooling the switching elements.

### BRIEF DESCRIPTION OF THE DRAWINGS

In the accompanying drawings:

FIG. 1 is a cross-sectional view of a rotating electric machine according to an exemplary embodiment;

FIG. 2 is a circuit diagram of the rotating electric machine;

FIG. 3 is a schematic view of the rotating electric machine along the rotation axis of a rotating shaft of the machine from a cover side, omitting the cover and showing control modules of a control section of the machine; and

FIG. 4 is a schematic view of the rotating electric machine along the rotation axis of the rotating shaft from the cover side, showing the cover fixed to a first frame of the machine.

### DESCRIPTION OF EMBODIMENT

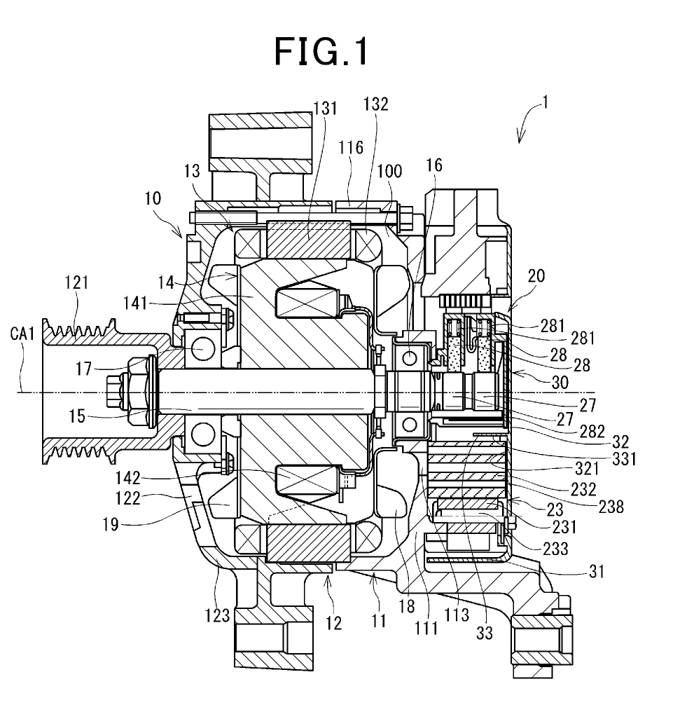

FIG. 1 shows the overall configuration of a rotating electric machine 1 according to an exemplary embodiment.

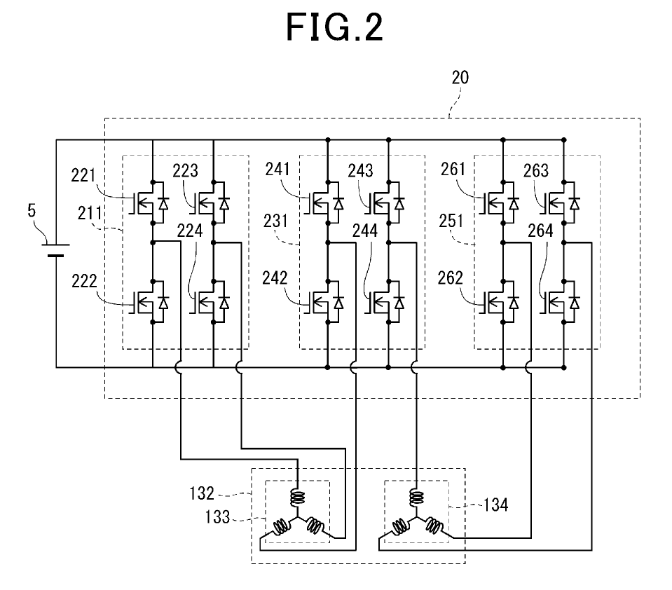

In the present embodiment, the rotating electric machine 1 is designed to be used in, for example, a vehicle. Moreover, the rotating electric machine 1 is configured as a motor-generator to selectively operate in a motor mode and a generator mode. In the motor mode, the rotating electric machine 1 generates, using electric power supplied from a battery 5 (see FIG. 2), drive power (or torque) for driving the vehicle. On the other hand, in the generator mode, the rotating electric machine 1 generates, using drive power supplied from an engine (not shown) of the vehicle, electric power for charging the battery 5.

As shown in FIG. 1, the rotating electric machine 1 includes a machine main body 10, a control section 20 and a cover 30.

The machine main body 10 is capable of generating torque upon being supplied with electric power and generating electric power upon being supplied with torque. The machine main body 10 includes a first frame 11, a second frame 12, a stator 13, a rotor 14, a rotating shaft 15, bearings 16 and 17, and cooling fans 18 and 19. In addition, the first and second frames 11 and 12 together correspond to a □housing□.

The first frame 11 is substantially cup-shaped (i.e., concave in shape). The first frame 11 has a bottom part 111 in which the bearing 16 is provided to rotatably support one end portion (i.e., a right end portion in FIG. 1) of the rotating shaft 15. In addition, the bottom part 111 corresponds to a □shaft-supporting part□.

On the opposite side of the bottom part 111 to the second frame 12, i.e., on the outside of the first frame 11, there is provided the control section 20.

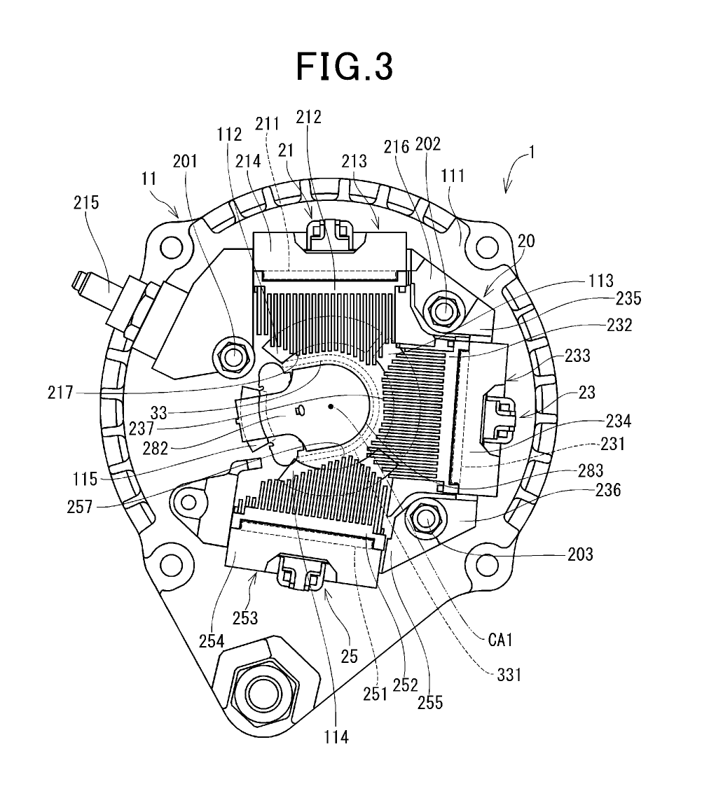

As shown in FIG. 3, in the bottom part 111 of the first frame 11, there are formed four ventilation holes (i.e., through-holes) 112, 113, 114 and 115 through which cooling air can flow from the outside to the inside of the first frame 11. The ventilation holes 112-115 are located in the vicinity of a brush holder 282 which will be described later. Moreover, of the four ventilation holes 112-115, the ventilation holes 112, 113 and 114 are located so that when viewed in a direction along a rotation axis CA1 of the rotating shaft 15, the ventilation holes 112, 113 and 114 respectively overlap heat sinks 212, 232 and 252 provided in the control section 20. In addition, the heat sinks 212, 232 and 252 will be described later.

Referring back to FIG. 1, the second frame 12 is also substantially cup-shaped (i.e., concave in shape). The first and second frames 11 and 12 are arranged to have their openings communicating with each other. Consequently, in the first and second frames 11 and 12, there is formed an accommodation space 100 in which the stator 13, the rotor 14 and the rotating shaft 15 are accommodated. To a bottom part of the second frame 12, there is mounted a connection part (e.g., a pulley) 121 that can be mechanically connected with a crankshaft (not shown) of the engine. Moreover, in the bottom part of the second frame 12, there is provided the bearing 17 to rotatably support another end portion (i.e., a left end portion in FIG. 1) of the rotating shaft 15. In addition, in the bottom part of the second frame 12, there is formed a ventilation hole (i.e., through-hole) 122 through which cooling air can flow from the outside to the inside of the second frame 12.

The first frame 11 has a tubular part 116 that extends from the bottom part 111 of the first frame 11 toward the second frame 12. Similarly, the second frame 12 has a tubular part 123 that extends from the bottom part of the second frame 12 toward the first frame 11.

The stator 13 is provided radially inside both the tubular part 116 of the first frame 11 and the tubular part 123 of the second frame 12 and radially outside the rotor 14.

The stator 13 includes an annular stator core 131 and stator coils 132 wound on the stator core 131. More particularly, in the present embodiment, as shown in FIG. 2, the stator coils 132 consist of a first three-phase stator coil 133 and a second three-phase stator coil 134.

In addition, it should be noted that the number of phases of the stator coils 132 may alternatively be two, or four or more. It also should be noted that the number of the stator coils 132 included in the stator 13 may alternatively be one, or three or more.

In the motor mode of the rotating electric machine 1, the stator 13 creates a rotating magnetic field with three-phase alternating current flowing in the stator coils 132. On the other hand, in the generator mode of the rotating electric machine 1, the stator 13 generates three-phase alternating current upon magnetic flux, which is generated by the rotor 14, crossing the stator coils 132.

The rotor 14 is rotatably provided radially inside the stator 13. The rotor 14 includes a rotor core 141 and a rotor coil 142 wound on the rotor core 141. The rotor 14 forms magnetic poles upon direct current (i.e., excitation current) flowing in the rotor coil 142.

The rotating shaft 15 is fixedly inserted in a center hole of the rotor core 141 so that the rotor 14 rotates together with the rotating shaft 15. In other words, the rotor 14 is fixed on the rotating shaft 15 to rotate together with the rotating shaft 15. As described previously, the end portions of the rotating shaft 15 are rotatably supported respectively by the bearings 16 and 17. In addition, the rotating shaft 15 rotates about the rotation axis CA1 thereof.

The cooling fan 18 is fixed to a first frame 11-side end surface of the rotor core 141, and thus located between the rotor core 141 and the bearing 16 in the direction of the rotation axis CA1 of the rotating shaft 15. On the other hand, the cooling fan 19 is fixed to a second frame 12-side end surface of the rotor core 141, and thus located between the rotor core 141 and the bearing 17 in the direction of the rotation axis CA1 of the rotating shaft 15. That is, both the cooling fans 18 and 19 are provided so as to rotate together with the rotor 14 and the rotating shaft 15.

The control section 20 is provided outside the machine main body 10. More specifically, the control section 20 is located on the opposite side of the bottom part 111 of the first frame 11 to the accommodation space 100.

The control section 20 includes a first control module 21, a second control module 23, a third control module 25, a pair of slip rings 27 and a pair of brushes 28.

In the motor mode of the rotating electric machine 1, the control section 20 controls the supply of electric power from the battery 5 to the machine main body 10. On the other hand, in the generator mode of the rotating electric machine 1, the control section 20 rectifies three-phase alternating current generated in the machine main body 10 into direct current and supplies the resultant direct current to the battery 5.

The first control module 21 is an assembly of components for forming a first inverter circuit and a first rectification circuit of the rotating electric machine 1. As shown in FIG. 3, the first control module 21 includes a power module 211, the aforementioned heat sink 212, and a busbar assembly 213.

The power module 211 is a switching element module which includes four switching elements for forming the first inverter circuit and the first rectification circuit, more particularly four MOSFETs 221, 222, 223 and 224 as shown in FIG. 2 in the present embodiment. The MOSFETs 221 and 222 are electrically connected in series with each other such that the source of the MOSFET 221 is electrically connected to the drain of the MOSFET 222. Similarly, the MOSFETs 223 and 224 are electrically connected in series with each other such that the source of the MOSFET 223 is electrically connected to the drain of the MOSFET 224.

As shown in FIG. 3, the heat sink 212 is provided only on the rotation axis CA1 side of the power module 211, i.e., only on the radially inner side of the power module 211. In other words, the heat sink 212 is located closer than the power module 211 to the rotation axis CA1 of the rotating shaft 15. The heat sink 212 is made of a metal and configured to dissipate heat generated in the power module 211. The configuration of the heat sink 212 will be described in detail later.

The busbar assembly 213 is an assembly of components for insulating and wiring the power module 211. The busbar assembly 213 includes a busbar (not shown) electrically connected with the power module 211, a sealing part 214, a power supply terminal 215 and a connection part 216.

The sealing part 214 is formed of a resin to fix and seal the busbar of the busbar assembly 213.

The power supply terminal 215 is provided on one side (i.e., the left side in FIG. 3) of the sealing part 214. The power supply terminal 215 is electrically connected with the busbar of the busbar assembly 213. Moreover, the power supply terminal 215 is also electrically connected to a positive terminal of the battery 5 (see FIG. 2) via an electric wire (not shown). In addition, the first control module 21 is fixed, at a position between the sealing part 214 and the power supply terminal 215, to the first frame 11 by means of a bolt 201.

The connection part 216 is provided on the opposite side of the sealing part 214 to the power supply terminal 215 (i.e., the right side of the sealing part 214 in FIG. 3). The connection part 216 is fixed to the first frame 11 by means of a bolt 202.

The second control module 23 is an assembly of components for forming the first inverter circuit, a second inverter circuit, the first rectification circuit and a second rectification circuit of the rotating electric machine 1. As shown in FIG. 3, the second control module 23 includes a power module 231, the aforementioned heat sink 232, and a busbar assembly 233.

The power module 231 is a switching element module which includes two switching elements for forming the first inverter circuit and the first rectification circuit and two switching elements for forming the second inverter circuit and the second rectification circuit, more particularly two MOSFETs 241 and 242 for forming the first inverter circuit and the first rectification circuit and two MOSFETs 243 and 244 for forming the second inverter circuit and the second rectification circuit as shown in FIG. 2 in the present embodiment. The MOSFETs 241 and 242 are electrically connected in series with each other such that the source of the MOSFET 241 is electrically connected to the drain of the MOSFET 242. Similarly, the MOSFETs 243 and 244 are electrically connected in series with each other such that the source of the MOSFET 243 is electrically connected to the drain of the MOSFET 244.

As shown in FIG. 3, the heat sink 232 is provided only on the rotation axis CA1 side of the power module 231, i.e., only on the radially inner side of the power module 231. In other words, the heat sink 232 is located closer than the power module 231 to the rotation axis CA1 of the rotating shaft 15. The heat sink 232 is made of a metal and configured to dissipate heat generated in the power module 231. The configuration of the heat sink 232 will be described in detail later.

The busbar assembly 233 is an assembly of components for insulating and wiring the power module 231. The busbar assembly 233 includes a busbar (not shown) electrically connected with the power module 231, a sealing part 234, and connection parts 235 and 236.

The sealing part 234 is formed of a resin to fix and seal the busbar of the busbar assembly 233.

The connection part 235 is provided on one side (i.e., the upper side in FIG. 3) of the sealing part 234. The connection part 235 is fixed, together with the connection part 216 of the first control module 21, to the first frame 11 by means of the bolt 202.

The connection part 236 is provided on the opposite side of the sealing part 234 to the connection part 235 (i.e., the lower side of the sealing part 234 in FIG. 3). The connection part 236 is fixed to the first frame 11 by means of a bolt 203.

The third control module 25 is an assembly of components for forming the second inverter circuit and the second rectification circuit of the rotating electric machine 1. As shown in FIG. 3, the third control module 25 includes a power module 251, the aforementioned heat sink 252, and a busbar assembly 253.

The power module 251 is a switching element module which includes four switching elements for forming the second inverter circuit and the second rectification circuit, more particularly four MOSFETs 261, 262, 263 and 264 as shown in FIG. 2 in the present embodiment. The MOSFETs 261 and 262 are electrically connected in series with each other such that the source of the MOSFET 261 is electrically connected to the drain of the MOSFET 262. Similarly, the MOSFETs 263 and 264 are electrically connected in series with each other such that the source of the MOSFET 263 is electrically connected to the drain of the MOSFET 264.

As shown in FIG. 3, the heat sink 252 is provided only on the rotation axis CA1 side of the power module 251, i.e., only on the radially inner side of the power module 251. In other words, the heat sink 252 is located closer than the power module 251 to the rotation axis CA1 of the rotating shaft 15. The heat sink 252 is made of a metal and configured to dissipate heat generated in the power module 251. The configuration of the heat sink 252 will be described in detail later.

The busbar assembly 253 is an assembly of components for insulating and wiring the power module 251. The busbar assembly 253 includes a busbar (not shown) electrically connected with the power module 251, a sealing part 254, and a connection part 255.

The sealing part 254 is formed of a resin to fix and seal the busbar of the busbar assembly 253.

The connection part 255 is provided on one side (i.e., the right side in FIG. 3) of the sealing part 254. The connection part 255 is fixed, together with the connection part 236 of the second control module 23, to the first frame 11 by means of the bolt 203.

The slip rings 27 and the brushes 28 are provided for supplying direct current (i.e., excitation current) to the rotor coil 142. Each of the slip rings 27 is fixed to an outer circumferential surface of the rotating shaft 15 via an insulating member. The brushes 28 are held by a brush holder 282 so that each of the brushes 28 has its distal end surface in pressed contact with an outer circumferential surface of a corresponding one of the slip rings 27. More specifically, each of the brushes 28 is pressed against the outer circumferential surface of the corresponding slip ring 27 by a spring 281 provided in the brush holder 282.

In addition, the brush holder 282, which holds the brushes 28 therein, is arranged radially outside that end portion of the rotating shaft 15 which is supported by the bearing 16 and radially inside the control modules 21, 23 and 25. The brush holder 282 has an outer wall surface 283 on the radially outer side (see FIG. 3).

The cover 30 is provided to cover the control section 20 from the opposite side of the control section 20 to the first frame 11 (i.e., on the outside of the first frame 11), thereby protecting the control section 20 from foreign substances such as water and dust. The cover 30 is made of a resin and configured to include a tubular part 31, a bottom part 32 and a partition wall 33.

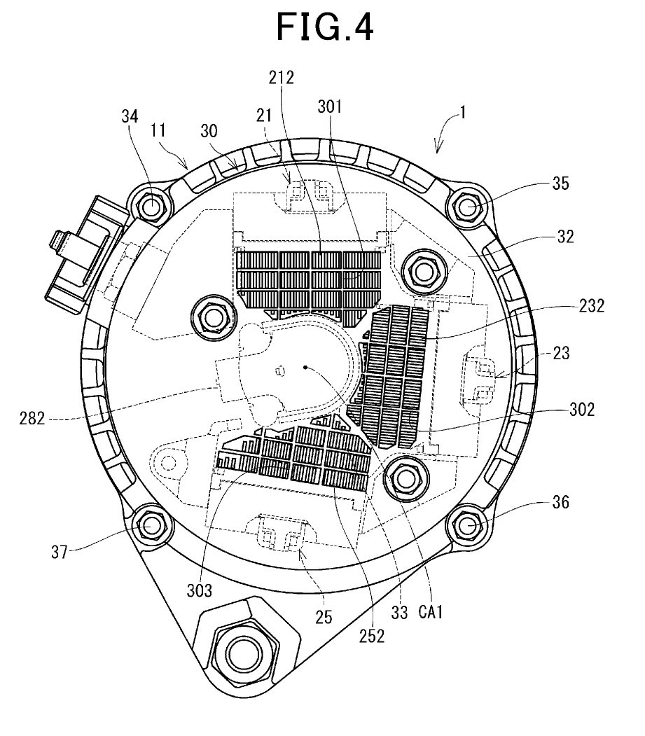

The tubular part 31 of the cover 30 is formed to extend substantially parallel to the rotation axis CA1 of the rotating shaft 15 and arranged to surround the control section 20. The tubular part 31 is fixed to the first frame 11 by means of bolts 34, 35, 36 and 37 (see FIG. 4).

The bottom part 32 of the cover 30 is substantially discoid in shape and arranged on the opposite side of the control section 20 to the bottom part 111 of the first frame 11. That is, the bottom part 32 is connected with an end of the tubular part 31 on the opposite side to the first frame 11 (i.e., a right end of the tubular part 31 in FIG. 1). Moreover, as shown in FIG. 4, in the bottom part 32, there are formed ventilation holes 301, 302 and 303 respectively in alignment with the heat sinks 212, 232 and 252 in a direction parallel to the rotation axis CA1 of the rotating shaft 15 (i.e., the direction perpendicular to the paper surface of FIG. 4). Consequently, the heat sinks 212, 232 and 252, which are located inside the cover 30, are visible from the outside of the cover 30 respectively through the ventilation holes 301, 302 and 303.

The partition wall 33 of the cover 30 is formed, on a substantially central portion of the bottom part 32 of the cover 30, to extend from the bottom part 32 toward the machine main body 10 (i.e., toward the first frame 11 and leftward in FIG. 1). Moreover, as shown in FIGS. 3 and 4, the partition wall 33 is formed to extend along the outer wall surface 283 of the brush holder 282 on the opposite side of the brush holder 282 to the rotation axis CA1 of the rotating shaft 15 (or on the radially outer side of the brush holder 282). The partition wall 33 is provided to prevent the heat sinks 212, 232 and 252 from making contact with the brush holder 282.

Next, the configuration of the heat sinks 212, 232 and 252 according to the present embodiment will be described in detail with reference to FIGS. 3 and 4.

As shown in FIG. 3, in the first, second and third control modules 21, 23 and 25, the heat sinks 212, 232 and 252 extend respectively from the power modules 211, 231 and 251 toward the rotation axis CA1 of the rotating shaft 15 (i.e., radially inward). Each of the heat sinks 212, 232 and 252 has a plurality of plate-shaped fins; the fins are arranged in parallel with each other in a direction substantially perpendicular to the rotation axis CA1 of the rotating shaft 15.

Moreover, as shown in FIG. 3, the heat sink 212 has a distal end 217 on the rotation axis CA1 side (or radially inner side); the distal end 217 of the heat sink 212 is constituted of distal ends of the fins of the heat sink 212 on the rotation axis CA1 side. Similarly, the heat sink 232 has a distal end 237 on the rotation axis CA1 side (or radially inner side); the distal end 237 of the heat sink 232 is constituted of distal ends of the fins of the heat sink 232 on the rotation axis CA1 side. The heat sink 252 has a distal end 257 on the rotation axis CA1 side (or radially inner side); the distal end 257 of the heat sink 252 is constituted of distal ends of the fins of the heat sink 252 on the rotation axis CA1 side. In the present embodiment, the distal ends 217, 237 and 257 of the heat sinks 212, 232 and 252 are formed to follow the shape of an outer wall surface 331 of the partition wall 33 of the cover 30 and arranged with a minimum allowable clearance provided between the distal ends 217, 237 and 257 and the outer wall surface 331. That is, the contour of the distal ends 217, 237 and 257 of the heat sinks 212, 232 and 252 conforms to the shape of the outer wall surface 331 of the partition wall 33. More particularly, in the present embodiment, the lengths of the fins of the heat sinks 212, 232 and 252 are variably set to have the distal ends of the fins located around the partition wall 33 of the cover 30 and as close to the outer wall surface 331 of the partition wall 33 as possible. Moreover, as described previously, the partition wall 33 of the cover 30 is formed to extend along the outer wall surface 283 of the brush holder 282. Therefore, the distal ends 217, 237 and 257 of the heat sinks 212, 232 and 252 are formed to follow the shape of the outer wall surface 283 of the brush holder 282 as well. In other words, the contour of the distal ends 217, 237 and 257 of the heat sinks 212, 232 and 252 also conforms to the shape of the outer wall surface 283 of the brush holder 282.

Moreover, as shown in FIG. 1, the heat sink 232 has an end surface 238 facing an inner wall surface 321 of the bottom part 32 of the cover 30; the end surface 238 is formed to extend along the inner wall surface 321 of the bottom part 32 of the cover 30 with a minimum allowable clearance provided between the end surface 238 and the inner wall surface 321. Similarly, though not shown in the figures, the heat sink 212 has an end surface facing the inner wall surface 321 of the bottom part 32 of the cover 30; the end surface is formed to extend along the inner wall surface 321 of the bottom part 32 of the cover 30 with the minimum allowable clearance provided between the end surface and the inner wall surface 321. The heat sink 252 has an end surface facing the inner wall surface 321 of the bottom part 32 of the cover 30; the end surface is formed to extend along the inner wall surface 321 of the bottom part 32 of the cover 30 with the minimum allowable clearance provided between the end surface and the inner wall surface 321.

Next, a manufacturing method of the rotating electric machine 1 according to the present embodiment will be described.

In the present embodiment, the manufacturing method of the rotating electric machine 1 includes a first assembly step, a second assembly step and a fixing step. In the first assembly step, the second control module 23 is assembled to the bottom part 111 of the first frame 11 from the opposite side of the bottom part 111 to the accommodation space 100. In the second assembly step, the first and third control modules 21 and 25 are assembled to the bottom part 111 of the first frame 11 so as to be located adjacent to the second control module 23 respectively on opposite sides of the second control module 23. In the fixing step, the first, second and third control modules 21, 23 and 25 are fixed to the bottom part 111 of the first frame 11 by means of the bolts 201, 202 and 203.

Next, operation of the rotating electric machine 1 will be described with reference to FIGS. 1 and 2.

As described previously, in the present embodiment, the rotating electric machine 1 is configured as a motor-generator to selectively operate in a motor mode and a generator mode in a vehicle.

In the motor mode, upon an ignition switch (not shown) of the vehicle being turned on, direct current is supplied from the battery 5 to the rotor coil 142 via the brushes 28 and the slip rings 27, causing magnetic poles to be formed on a radially outer periphery of the rotor 14. At the same time, direct current is also supplied from the battery 5 to the power modules 211, 231 and 251. Then, the six MOSFETs 221, 222, 223, 224, 241 and 242, which together form the first inverter circuit, are turned on or off at predetermined timings, thereby converting the direct current supplied from the battery 5 into three-phase alternating current. Similarly, the six MOSFETs 243, 244, 261, 262, 263 and 264, which together form the second inverter circuit, are also turned on or off at predetermined timings, thereby converting the direct current supplied from the battery 5 into three-phase alternating current. However, the predetermined timings at which the six MOSFETs forming the second inverter circuit are turned on or off are different from the predetermined timings at which the six MOSFETs forming the first inverter circuit are turned on or off. Consequently, the three-phase alternating current outputted from the second inverter circuit is different in phase from the three-phase alternating current outputted from the first inverter circuit. The three-phase alternating current outputted from the first inverter circuit and the three-phase alternating current outputted from the second inverter circuit are respectively supplied to the first and second three-phase stator coils 133 and 134, causing the machine main body 10 to generate drive power for driving the vehicle.

In the generator mode, direct current is supplied from the battery 5 to the rotor coil 142 via the brushes 28 and the slip rings 27, causing magnetic poles to be formed on the radially outer periphery of the rotor 14. Moreover, drive power is transmitted from the crankshaft of the engine of the vehicle to the connection part 121 of the machine main body 10, causing three-phase alternating current to be generated in each of the first and second three-phase stator coils 133 and 134. Then, the six MOSFETs 221, 222, 223, 224, 241 and 242, which together form the first rectification circuit, are turned on or off at predetermined timings, thereby rectifying the three-phase alternating current generated in the first three-phase stator coil 133 into direct current. Similarly, the six MOSFETs 243, 244, 261, 262, 263 and 264, which together form the second rectification circuit, are also turned on or off at predetermined timings, thereby rectifying the three-phase alternating current generated in the second three-phase stator coil 134 into direct current. Both the direct current outputted from the first rectification circuit and the direct current outputted from the second rectification circuit are supplied to the battery 5 to charge it.

During operation of the rotating electric machine 1, cooling air is caused by rotation of the cooling fans 18 and 19 along with the rotor 14 and the rotating shaft 15 to flow from the outside to the inside of the rotating electric machine 1. Specifically, the cooling air, which has flowed from the outside of the rotating electric machine 1 to the inside of the cover 30 through the ventilation holes 301, 302 and 303 of the cover 30, further flows along the rotation axis CA1 of the rotating shaft 15 into the accommodation space 100 through gaps between adjacent fins of the heat sinks 212, 232 and 252 and the ventilation holes 112, 113 and 114 of the first frame 11. Moreover, the cooling air, which has flowed into the accommodation space 100, further flows in a direction substantially perpendicular to the rotation axis CA1 to the outside of the rotating electric machine 1 through a gap between the first and second frames 11 and 12.

With the above flow of the cooling air, heat generated in the power modules 211, 231 and 251 during the conversion of direct current into three-phase alternating current or the conversion of three-phase alternating current into direct current is dissipated via the heat sinks 212, 232 and 252.

According to the present embodiment, it is possible to achieve the following advantageous effects.

In the rotating electric machine 1 according to the present embodiment, the heat sinks 212, 232 and 252 are provided only on the rotation axis CA1 side of the power modules 211, 231 and 251, i.e., only on the radially inner side of the power modules 211, 231 and 251. Therefore, most of the cooling air passing through the heat sinks 212, 232 and 252 flows along a single, relatively simple flow path, i.e., flows first along the rotation axis CA1 after flowing from the outside of the rotating electric machine 1 to the inside of the cover 30 until flowing into the accommodation space 100 and then in the direction substantially perpendicular to the rotation axis CA1 after flowing into the accommodation space 100 until flowing out of the rotating electric machine 1. Consequently, it becomes possible to prevent the efficiency of cooling the power modules 211, 231 and 251 from being lowered due to stagnation of the cooling air caused by collision between different flows of the cooling air. Moreover, providing the heat sinks 212, 232 and 252 on the rotation axis CA1 side of the power modules 211, 231 and 251, it becomes possible to maximize the contact area of the heat sinks 212, 232 and 252 with the cooling air. As a result, it becomes possible to improve the efficiency of cooling the power modules 211, 231 and 251.

In the rotating electric machine 1 according to the present embodiment, the end surfaces of the heat sinks 212, 232 and 252, which face the inner wall surface 321 of the bottom part 32 of the cover 30, are formed to extend along the inner wall surface 321 of the bottom part 32 of the cover 30 with the minimum allowable clearance provided between the end surfaces and the inner wall surface 321. Consequently, it becomes possible to maximize the length of the heat sinks 212, 232 and 252 in a direction parallel to the rotation axis CA1 of the rotating shaft 15 and thus the contact area of the heat sinks 212, 232 and 252 with the cooling air. As a result, it becomes possible to further improve the efficiency of cooling the power modules 211, 231 and 251.

In the rotating electric machine 1 according to the present embodiment, the distal ends 217, 237 and 257 of the heat sinks 212, 232 and 252 are formed to follow the shape of the outer wall surface 283 of the brush holder 282. Consequently, it becomes possible to maximize the lengths of the fins of the heat sinks 212, 232 and 252 in the extending directions of the fins substantially perpendicular to the rotation axis CA1 of the rotating shaft 15 and thus the contact area of the heat sinks 212, 232 and 252 with the cooling air. As a result, it becomes possible to further improve the efficiency of cooling the power modules 211, 231 and 251.

In the rotating electric machine 1 according to the present embodiment, in the bottom part 32 of the cover 30, there are formed the ventilation holes 301, 302 and 303 that each penetrate the bottom part 32 in a direction parallel to the rotation axis CA1 of the rotating shaft 15 (i.e., the direction perpendicular to the paper surface of FIG. 4) and are respectively aligned with the heat sinks 212, 232 and 252 in the direction parallel to the rotation axis CA1. Consequently, the cooling air, which has flowed from the outside to the inside of the cover 30 through the ventilation holes 301, 302 and 303, will further flow to the heat sinks 212, 232 and 252 without being stagnated and thus reliably make contact with the heat sinks 212, 232 and 252. As a result, it becomes possible to further improve the efficiency of cooling the power modules 211, 231 and 251.

In the rotating electric machine 1 according to the present embodiment, in the bottom part 111 of the first frame 11, there are formed the ventilation holes 112, 113 and 114 that each penetrate the bottom part 111 in a direction parallel to the rotation axis CA1 of the rotating shaft 15 and respectively overlap the heat sinks 212, 232 and 252 in the direction parallel to the rotation axis CA1. Moreover, as described previously, the heat sinks 212, 232 and 252 are provided only on the rotation axis CA1 side of the power modules 211, 231 and 251. Therefore, the ventilation holes 112, 113 and 114 are also formed only on the rotation axis CA1 side of the power modules 211, 231 and 251. Consequently, it becomes possible to prevent the mechanical strength of the first frame 11 from being excessively lowered due to the ventilation holes 112, 113 and 114 formed therein while improving the efficiency of cooling the power modules 211, 231 and 251.

The manufacturing method of the rotating electric machine 1 according to the present embodiment includes the first and second assembly steps. In the first assembly step, the second control module 23 is assembled to the bottom part 111 of the first frame 11 from the opposite side of the bottom part 111 to the accommodation space 100. In the second assembly step, the first and third control modules 21 and 25 are assembled to the bottom part 111 of the first frame 11 so as to be located adjacent to the second control module 23 respectively on opposite sides of the second control module 23. Consequently, compared to the case of first assembling the first control module 21 or the third control module 25 and then assembling the remaining two control modules to the bottom part 111 of the first frame 11, it becomes possible to reduce assembly errors of the three control modules 21, 23, and 25, thereby reliably assembling them to desired positions on the bottom part 111 of the first frame 11. Hence, it also becomes possible to increase the sizes of the heat sinks 212, 232 and 252 of the control modules 21, 23, and 25 to the extent that the minimum allowable clearances can be secured between the heat sinks 212, 232 and 252 and the inner wall surface 321 of the bottom part 32 of the cover 30 and between the heat sinks 212, 232 and 252 and the outer wall surface 331 of the partition wall 33 of the cover 30. As a result, it becomes possible to further improve the efficiency of cooling the power modules 211, 231 and 251.

While the above particular embodiment has been shown and described, it will be understood by those skilled in the art that various modifications, changes, and improvements may be made without departing from the spirit of the present disclosure.

For example, in the above-described embodiment, the rotting electric machine 1 is designed to be used in a vehicle. However, the present disclosure can also be applied to rotating electric machines for other uses.

In the above-described embodiment, the distal ends 217, 237 and 257 of the heat sinks 212, 232 and 252 are formed to follow the shape of the outer wall surface 283 of the brush holder 282. However, the distal ends 217, 237 and 257 of the heat sinks 212, 232 and 252 may also be formed without following the shape of the outer wall surface 283 of the brush holder 282.

In the above-described embodiment, the bottom part 32 of the cover 30 has the ventilation holes 301, 302 and 303 formed respectively in alignment with the heat sinks 212, 232 and 252 in a direction parallel to the rotation axis CA1 . However, the ventilation holes 301, 302 and 303 may also be formed in misalignment with the heat sinks 212, 232 and 252 in the direction parallel to the rotation axis CA1 . In addition, the bottom part 32 of the cover 30 may have no ventilation holes formed therein.

In the above-described embodiment, the bottom part 111 of the first frame 11 has the ventilation holes 112, 113 and 114 formed to respectively overlap the heat sinks 212, 232 and 252 in a direction parallel to the rotation axis CA1 . However, the ventilation holes 112, 113 and 114 may also be formed so as not to overlap the heat sinks 212, 232 and 252 in the direction parallel to the rotation axis CAl.

In the above-described embodiment, the MOSFETs are employed in the power modules 211, 231 and 251. However, other switching elements, such as diodes, may alternatively be employed in the power modules 211, 231 and 251.

In the case of the power modules 211, 231 and 251 employing diodes, the heat sinks 212, 232 and 252 would be charged (i.e., have an electric potential not equal to the ground potential). In contrast, in the above-described embodiment, since the MOSFETs are employed in the power modules 211, 231 and 251, the heat sinks 212, 232 and 252 are prevented from being charged. Therefore, the sizes of the heat sinks 212, 232 and 252 are allowed to be increased to the extent that the minimum allowable clearances can be secured between the heat sinks 212, 232 and 252 and the inner wall surface 321 of the bottom part 32 of the cover 30 and between the heat sinks 212, 232 and 252 and the outer wall surface 331 of the partition wall 33 of the cover 30.

In the above-described embodiment, the stator 13 includes two three-phase stator coils, i.e., the first three-phase stator coil 133 and the second three-phase stator coil 134. Moreover, the MOSFETs forming the first inverter circuit that converts the direct current supplied from the battery 5 into the three-phase alternating current supplied to the first three-phase stator coil 133 are turned on or off at different predetermined timings from the MOSFETs forming the second inverter circuit that converts the direct current supplied from the battery 5 into the three-phase alternating current supplied to the second three-phase stator coil 134. However, the stator 13 may alternatively include only a single three-phase stator coil.

In addition, in the above-described embodiment, by turning on or off the MOSFETs forming the first inverter circuit at different predetermined timings from the MOSFETs forming the second inverter circuit, it is possible to reduce noise included in the three-phase alternating currents outputted from the first and second inverter circuits.

What is claimed is:

1. A rotating electric machine comprising:
a rotating shaft having a rotation axis about which the rotating shaft is rotatable;
a rotor fixed on the rotating shaft to rotate together with the rotating shaft;
a stator provided radially outside the rotor and including a stator coil;
a housing that rotatably supports the rotating shaft and accommodates both the rotor and the stator therein, the housing having a shaft-supporting part that supports an end portion of the rotating shaft;
a plurality of control modules capable of supplying multi-phase alternating current to the stator coil and rectifying multi-phase alternating current generated in the stator coil into direct current, the control modules being arranged outside the shaft-supporting part of the housing and around the rotating shaft, each of the control modules including a plurality of switching elements electrically connected with the stator coil, and a heat sink provided only on a rotation axis side, where the rotation axis of the rotating shaft is located, of the switching elements; and
a cover that covers the control modules on an outside of the housing, the cover having a bottom part arranged on an opposite side of the control modules to the shaft-supporting part of the housing,
wherein
each of the heat sinks of the control modules has an end surface facing an inner wall surface of the bottom part of the cover, the end surface being formed to extend along the inner wall surface of the bottom part of the cover.

2. The rotating electric machine as set forth in claim 1, further comprising a brush holder that holds therein brushes for supplying direct current to a rotor coil provided in the rotor, the brush holder being arranged radially outside the end portion of the rotating shaft and radially inside the control modules,
wherein
each of the heat sinks of the control modules has a distal end on a radially inner side,
the brush holder has an outer wall surface on a radially outer side, and
the distal ends of the heat sinks are formed to follow the shape of the outer wall surface of the brush holder.

3. The rotating electric machine as set forth in claim 1, wherein in the bottom part of the cover, there are formed a plurality of ventilation holes that each penetrate the bottom part in a direction parallel to the rotation axis of the rotating shaft and are respectively aligned with the heat sinks of the control modules in the direction parallel to the rotation axis.

4. The rotating electric machine as set forth in claim 1, wherein in the shaft-supporting part of the housing, there are formed a plurality of ventilation holes that each penetrate the shaft-supporting part in a direction parallel to the rotation axis of the rotating shaft and respectively overlap the heat sinks of the control modules in the direction parallel to the rotation axis.
